(19) United States
(12) Patent Application Publication
(10) Pub. No.: US 2025/0383595 A1
(43) Pub. Date: Dec. 18, 2025

(54) EUV PHOTOMASKS AND MANUFACTURING METHOD THEREOF

(71) Applicant: Taiwan Semiconductor Manufacturing Company, Ltd., Hsinchu (TW)

(72) Inventors: Ching-Fang YU, Hsinchu (TW); Pei-Cheng HSU, Hsinchu (TW); Hsin-Chang LEE, Hsinchu (TW); Chia-Jen CHEN, Hsinchu (TW)

(73) Assignee: Taiwan Semiconductor Manufacturing Company, Ltd., Hsinchu (TW)

(21) Appl. No.: 18/917,569

(22) Filed: Oct. 16, 2024

Related U.S. Application Data
(60) Provisional application No. 63/660,294, filed on Jun. 14, 2024.

(51) Int. Cl. G03F 1/24

(52) U.S. Cl. CPC G03F 1/24

(57) ABSTRACT

A method of manufacturing a reflective mask includes forming a sacrificial layer over a substrate and forming a reflective multilayer over the sacrificial layer. A capping layer is formed over the reflective multilayer. An absorber layer is formed over the capping layer. An opening is formed in the absorber layer, the capping layer, and the reflective layer exposing a portion of the sacrificial layer, and a protective layer is formed along sidewalls of the opening. The protective layer is made of material from the sacrificial layer.

### RELATED APPLICATION

This application claims priority to U.S. Provisional Patent Application No. 63/660,294 filed Jun. 14, 2024, the entire contents of which are incorporated herein by reference.

### BACKGROUND

Photolithography operations are one of the key operations in the semiconductor manufacturing process. Photolithography techniques include ultraviolet lithography, deep ultraviolet lithography, and extreme ultraviolet lithography (EUVL). The photomask is an important component in photolithography operations. It is critical to fabricate EUV photomasks having a high contrast with a high reflectivity part and a high absorption part.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B show an EUV photomask blank and an EUV photomask according to embodiments of the present disclosure.

FIGS. 2A, 2B, 2C, 2D, and 2E show EUV photomask blanks according to embodiments of the present disclosure.

FIGS. 3, 4, 5, 6, 7, 8, 9, 10, and 11 schematically illustrate a method of fabricating an EUV photomask according to an embodiment of the present disclosure.

FIG. 12A schematically illustrates an operation in a method of fabricating an EUV photomask according to embodiments of the present disclosure. FIG. 12B schematically illustrates a black region of an EUV photomask according to an embodiment of the present disclosure.

FIGS. 13, 14, 15, 16, 17, 18, 19, 20, 21, 22, and 23 schematically illustrate a method of fabricating an EUV photomask according to an embodiment of the present disclosure.

FIGS. 24A and 24B show an EUV photomask blank and an EUV photomask according to embodiments of the present disclosure.

FIG. 25A schematically illustrates a plan view of an EUV photomask according to embodiments of the present disclosure. FIG. 25B shows a detailed cross sectional view of a portion of the photomask of FIG. 25A.

FIG. 26A shows a flowchart of a method making a semiconductor device, and FIGS. 26B, 26C, 26D, and 26E show a sequential manufacturing operation of a method of making a semiconductor device in accordance with embodiments of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described. Furthermore, the term “based” means that the composition, compound, or alloy contains 50 wt. % or more by weight of the material on which it is based.

Embodiments of the present disclosure provide a method of manufacturing an EUV photomask, an EUV photomask, and an EUV photomask blank. More specifically, the present disclosure provides techniques to prevent or suppress damage to the reflective multilayer of an EUV photomask. Because Si and Mo have different etch selectivities, a saw-like sidewall surface of the reflective multilayer surface can be produced during the photomask manufacturing process. A silicon dioxide capping layer has been proposed to protect the reflective multilayer sidewalls. However, silicon dioxide has a high index of refraction (e.g.—n=0.974) and a low extinction coefficient (k=0.012) at EUV wavelengths. Thus, the silicon dioxide capping layer has a high reflectivity in the black border region and may introduce undesirable stray reflections into the imaged EUV radiation. Embodiments of the present disclosure overcome these shortcomings of the saw-like reflective multilayer sidewall surface and the high reflectivity of silicon dioxide capping layers.

EUV lithography (EUVL) employs scanners using light in the extreme ultraviolet (EUV) region, having a wavelength of about 1 nm to about 100 nm, for example, 13.5 nm. The mask is a critical component of an EUVL system. Because the optical materials are not transparent to EUV radiation, EUV photomasks are reflective masks. Circuit patterns are formed in an absorber layer disposed over the reflective structure. The absorber has a low EUV reflectivity, for example, less than 3-5%.

The present disclosure provides an EUV reflective photomask having a low reflective (high absorbing) absorber structure.

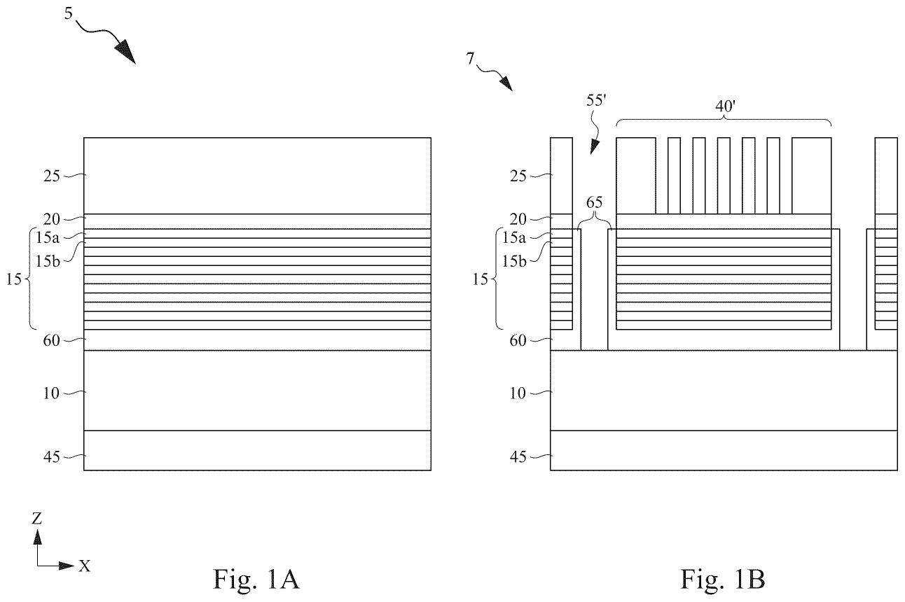

FIGS. 1A and 1B show an EUV reflective photomask blank 5 and an EUV reflective photomask 7, respectively, according to embodiments of the present disclosure. In some embodiments, the EUV photomask 7 with circuit patterns 40′ is formed from an EUV photomask blank 5. The EUV photomask blank 5 includes a substrate 10, a multilayer Mo/Si stack 15 of multiple alternating layers of silicon and molybdenum, a capping layer 20, and an absorber layer 25. Further, a backside conductive layer 45 is formed on the backside of the substrate 10.

The substrate 10 is formed of a low thermal expansion material in some embodiments. In some embodiments, the substrate is a low thermal expansion glass or quartz, such as fused silica or fused quartz. In some embodiments, the low thermal expansion glass substrate transmits light at visible wavelengths, a portion of the infrared wavelengths near the visible spectrum (near infrared), and a portion of the ultraviolet wavelengths.

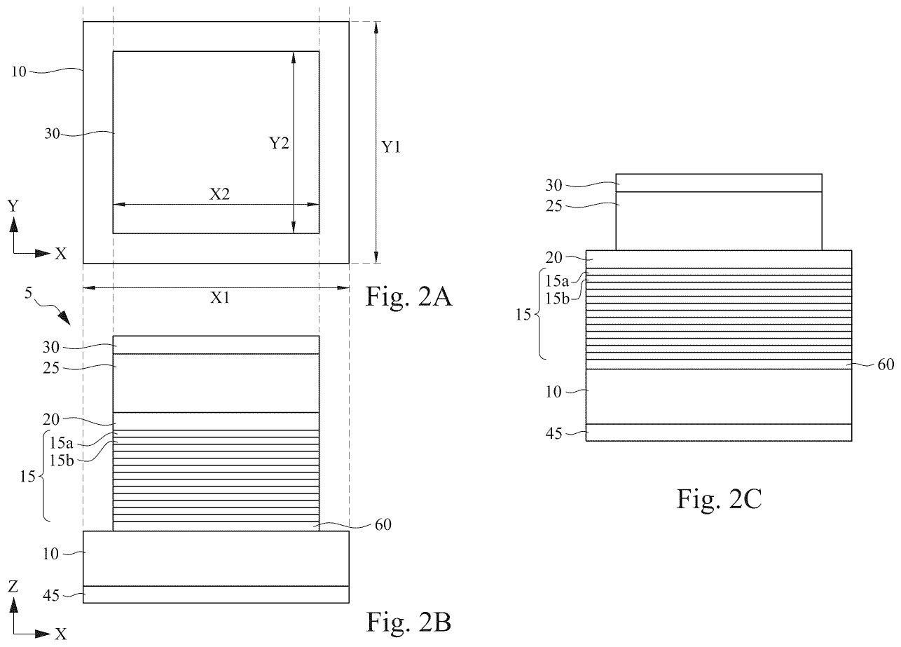

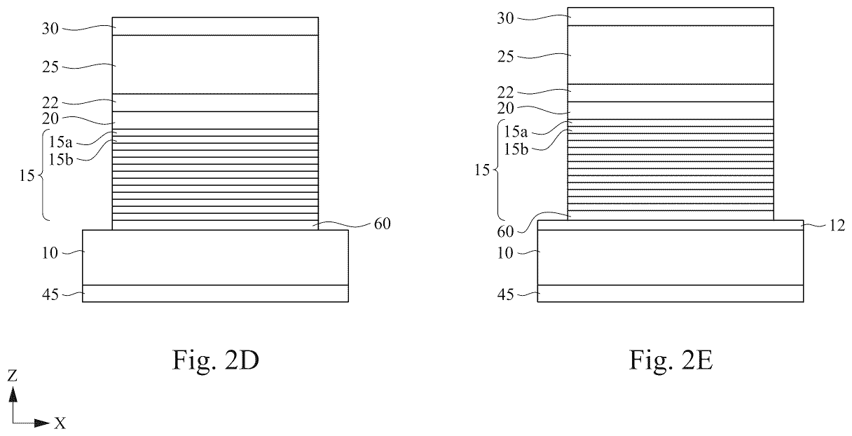

FIG. 2A is a plan view (viewed from the top) and FIG. 2B is a cross sectional view along the X direction of a photomask blank according to embodiments of the disclosure.

In some embodiments, the low thermal expansion glass substrate absorbs extreme ultraviolet wavelengths and deep ultraviolet wavelengths near the extreme ultraviolet. In some embodiments, the size of the substrate 10 is 152 mm×152 mm having a thickness of about 20 mm. In other embodiments, the size of the substrate 10 is smaller than 152 mm×152 mm and equal to or greater than 148 mm×148 mm. The shape of the substrate 10 is square or rectangular.

In some embodiments, the functional layers above the substrate (the multilayer Mo/Si stack 15, the capping layer 20, the absorber layer 25 and the hard mask layer 30) have a smaller width than the substrate 10. In some embodiments, the size of the functional layers is in a range from about 138 mm×138 mm to 142 mmx 142 mm. The shape of the functional layers can be square or rectangular.

In other embodiments, the absorber layer 25 and the hard mask layer 30 have a size in the range from about 138 mm×138 mm to 142 mmx 142 mm and smaller than the substrate 10, the multilayer Mo/Si stack 15 and the capping layer 20 as shown in FIG. 2C. The smaller size of one or more of the functional layers can be formed by using a frame shaped cover having an opening in a range from about 138 mm×138 mm to 142 mmx 142 mm, when forming the respective layers by, for example, sputtering. In other embodiments, all of the layers above the substrate 10 have the same size as the substrate 10.

In some embodiments, the Mo/Si multilayer stack 15 includes from about 30 alternating layers each of silicon 15a and molybdenum 15b to about 60 alternating layers each of silicon and molybdenum. In certain embodiments, from about 40 to about 50 alternating layers each of silicon 15a and molybdenum 15b are formed. In some embodiments, the reflectivity is higher than about 70% for wavelengths of interest e.g., 13.5 nm. In some embodiments, the silicon and molybdenum layers are formed by chemical vapor deposition (CVD), plasma-enhanced CVD (PECVD), atomic layer deposition (ALD), physical vapor deposition (PVD) (sputtering), or any other suitable film forming method. In some embodiments, each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each silicon layer is about 4 nm and the thickness of each molybdenum layer is about is about 3 nm.

In other embodiments, the multilayer stack 15 includes alternating molybdenum layers and beryllium layers. In some embodiments, the number of layers in the multilayer stack 15 is in a range from about 20 to about 100 although any number of layers is allowed as long as sufficient reflectivity is maintained for imaging the target substrate. In some embodiments, the reflectivity is higher than about 70% for wavelengths of interest e.g., 13.5 nm. In some embodiments, the multilayer stack 15 includes about 30 to about 60 alternating layers of Mo and Be. In other embodiments of the present disclosure, the multilayer stack 15 includes about 40 to about 50 alternating layers each of Mo and Be.

A sacrificial layer 60 is formed over the substrate 10 before forming the reflective multilayer stack 15. The sacrificial layer can be made of materials having a high extinction coefficient k. In some embodiments, the extinction coefficient is greater than 0.02 (k>0.02). In some embodiments, the extinction coefficient ranges from about 0.02 to about 0.04. In some embodiments, the sacrificial layer 60 is a metal layer including one or more of Ru, Al, Rh, W, Ta, Hf, Ir, Ti, Pd, Zn, Cr, Ni, Zr, Pb, and alloys thereof. In some embodiments, the sacrificial layer 60 is doped with one or more of N, B, C, and O. The dopant concentration in the sacrificial layer 60 ranges from about 1 at. % to about 35 at. % in some embodiments, and from about 2 at. % to about 25 at. % in other embodiments. The sacrificial layer 60 may be made by a physical vapor deposition operation, such as sputtering, although other suitable deposition processes can be used. In some embodiments, the sacrificial layer 60 has a thickness ranging from about 1 nm to about 60 nm. In other embodiments, the thickness of the sacrificial layer 60 ranges from about 2 nm to about 30 nm.

If the sacrificial layer 60 is doped with N, B, C, or O, the doping can be performed by introducing an N-based gas, a B-based gas, a C-based gas, or an O-based gas, along with a carrier gas (such as Ar) during the sputtering operation to form the sacrificial layer. In some embodiments, a metal boride (MeB) is used to provide boron doping. In some embodiments, the doped elements change the microstructure of the sacrificial layer 60.

The capping layer 20 is disposed over the Mo/Si multilayer 15 to prevent oxidation of the multilayer stack 15 in some embodiments. In some embodiments, the capping layer 20 is made of ruthenium, a ruthenium alloy (e.g., RuNb, RuZr, RuZrN, RuRh, RuNbN, RuRhN, RuV or RuVN) or a ruthenium based oxide (e.g., RuO₂, RuNbO, RuVO or RuON), having a thickness of from about 2 nm to about 10 nm. In certain embodiments, the thickness of the capping layer 20 is from about 2 nm to about 5 nm. In some embodiments, the capping layer 20 has a thickness of 3.5 nm±10%. In some embodiments, the capping layer 20 is formed by chemical vapor deposition, plasma-enhanced chemical vapor deposition, atomic layer deposition, physical vapor deposition (e.g., sputtering), or any other suitable film forming method. In other embodiments, a Si layer is used as the capping layer 20.

The absorber layer 25 is disposed over the capping layer 20. In embodiments of the present disclosure, the absorber layer 25 includes a Cr based material, such as Cr, CrO, CrON, CrB, and/or CrBN. In some embodiments where nitrogen is present in the Cr based material a nitrogen content of the Cr based material is about 16 atomic % to about 40 atomic %, and in some embodiments where oxygen is present in the Cr based material an oxygen content of the Cr based material is more than 0 atomic to about 30 atomic %. In some embodiments, the absorber layer 25 has a multilayered structure of Cr, CrO, CrON, CrB, and/or CrBN. In some embodiments, the thickness of the absorber layer 25 is in a range from about 20 nm to about 100 nm, is in a range from about 25 nm to about 75 nm in other embodiments, is in a range from about 35 nm to about 50 nm in other embodiments, and is in a range of about 40 nm to about 46 nm in yet other embodiments. In some embodiments, when the Cr-based material includes oxygen, the amount of the oxygen is in a range from about 5 atomic % to about 30 atomic %, and is in a range from about 10 atomic % to about 25 atomic % in other embodiments. In some embodiments, the absorber layer 25 further includes one or more elements of Co, Te, Hf and/or Ni.

In some embodiments, the absorber layer 25 is made of TaN, TaO, TaB, TaBO, or TaBN. In other embodiments, the absorber layer 25 includes an Ir-based material including elemental iridium (not compound) or an iridium alloy, such as IrPt, IrAl, IrRu, IrB, IrN, IrSi, and/or IrTi. In other embodiments, the absorber layer 25 includes a Pt-based material including elemental platinum (not compound) or a Pt alloy, such as PtAl, PtRu, PtB, PtSi, PtN, and/or PtTi. In other embodiments, the absorber layer 25 includes a Co-based material including elemental cobalt (not compound) or a Co alloy, such as CoO, CoB, CoBN, CON, and/or CoSi.

In some embodiments, the absorber layer 25 is formed by chemical vapor deposition, plasma-enhanced chemical vapor deposition, atomic layer deposition, physical vapor deposition, or any other suitable film forming method. One or more layers are disposed between the capping layer 20 and the absorber layer 25 as set forth below in some embodiments.

In some embodiments, the absorber layer 25 further includes one or more elements, such as Si, B, Ge, Al, As, Sb, Te, Se and/or Bi,

In some embodiments, an antireflective layer (not shown) is optionally disposed over the absorber layer 25. The antireflective layer is made of a silicon oxide in some embodiments, and has a thickness of from about 2 nm to about 10 nm. In other embodiments, a TaBO layer having a thickness in a range from about 12 nm to about 18 nm is used as the antireflective layer. In some embodiments, the thickness of the antireflective layer is from about 3 nm to about 6 nm. In some embodiments, the antireflective layer is formed by chemical vapor deposition, plasma-enhanced chemical vapor deposition, atomic layer deposition, physical vapor deposition, or any other suitable film forming method.

A hard mask layer 30 is disposed over the absorbing layer 25 in some embodiments. The hard mask layer 30 is formed over the antireflective layer in some embodiments. In some embodiments, the hard mask layer 30 is made of a Ta based material, such as TaB, TaO, TaBO or TaBN. In other embodiments, the hard mask layer 30 is made of silicon, a silicon-based compound (e.g., silicon nitride or silicon oxynitride), ruthenium or a ruthenium-based compound (e.g.—RuB), or a Cr-based material (e.g., CrON). The choice of hard mask layer material depends on the choice of material for the absorber layer. The hard mask layer material can be selected so that the hard mask layer 30 and the absorber layer 25 have different etch selectivities. The hard mask layer 30 has a thickness of about 4 nm to about 20 nm in some embodiments. In some embodiments, the hard mask layer 30 is formed by chemical vapor deposition, plasma-enhanced chemical vapor deposition, atomic layer deposition, physical vapor deposition, or any other suitable film forming method.

In some embodiments, the backside conductive layer 45 is disposed on a second main surface of the substrate 10 opposing the first main surface of the substrate 10 on which the Mo/Si multilayer 15 is formed. In some embodiments, the backside conductive layer 45 is made of tantalum boride or another Ta-based conductive material. In some embodiments, the tantalum boride is crystalline. In some embodiments, crystalline tantalum boride includes one or more of TaB, Ta₅B₆, Ta₃B₄, and TaB₂. In other embodiments, the tantalum boride is polycrystalline or amorphous. In other embodiments, the backside conductive layer 45 is made of a Cr-based conductive material (e.g.—CrN or CrON). In some embodiments, sheet resistance of the backside conductive layer 45 is equal to or less than 20Ω/□. In certain embodiments, the sheet resistance of the backside conductive layer 45 is equal to or greater than 0.1Ω/□. In some embodiments, the surface roughness Ra of the backside conductive layer 45 is equal to or less than 0.25 nm. In certain embodiments, the surface roughness Ra of the backside conductive layer 45 is equal to or greater than 0.05 nm. Further, in some embodiments, the flatness of the backside conductive layer 45 is equal to or less than 50 nm. In some embodiments, the flatness of the backside conductive layer 45 is more than 1 nm. A thickness of the backside conductive layer 45 is in a range from about 50 nm to about 400 nm in some embodiments. In other embodiments, the backside conductive layer 45 has a thickness of about 50 nm to about 100 nm. In certain embodiments, the thickness of the backside conductive layer 45 is in a range from about 65 nm to about 75 nm. In some embodiments, the backside conductive layer 45 is formed by atmospheric chemical vapor deposition (CVD), low pressure CVD, plasma-enhanced CVD, laser-enhanced CVD, atomic layer deposition (ALD), molecular beam epitaxy (MBE), physical vapor deposition including thermal deposition, pulsed laser deposition, electron-beam evaporation, ion beam assisted evaporation and sputtering, or any other suitable film forming method. In cases of CVD, source gases include TaCl₅ and BCl₃ in some embodiments.

A black border 55′ is formed in the periphery of the photomask 7 surrounding the pattern 40′ in the absorber layer. The black border 55′ is a frame shape area created by removing all the multilayers on the EUV photomask in the region around a circuit pattern area 40′. The black border is created to prevent exposure of adjacent fields when printing an EUV photomask pattern on a wafer. The width of the black border is in a range from about 1 mm to about 5 mm in some embodiments.

A protective layer 65 is formed over the sidewalls of the reflective multilayer 15 in the black border 55′. The protective layer 65 is made of the same material as the sacrificial layer 60. In some embodiments, the thickness of the protective layer 65 ranges from about 1 nm to about 12 nm, and in other embodiments, the thickness of the protective layer ranges from about 2 nm to about 6 nm.

In some embodiments, as shown in FIG. 2D, an additional (intermediate) layer 22 is formed between the capping layer 20 and the absorber layer 25. The additional layer 22 protects the capping layer in some embodiments. In some embodiments, the additional layer 22 includes Ta based material, such as TaB, TaO, TaBO, or TaBN, silicon, a silicon-based compound (e.g., silicon oxide, silicon nitride, silicon oxynitride, or MoSi), ruthenium, or a ruthenium-based compound (e.g.—RuB). The additional layer 22 has a thickness of about 2 nm to about 20 nm in some embodiments. In some embodiments, the additional layer 22 is formed by chemical vapor deposition, plasma-enhanced chemical vapor deposition, atomic layer deposition, physical vapor deposition, or any other suitable film forming method. In some embodiments, the additional layer 22 functions as an etch stop layer during a patterning operation of the absorber layer.

In other embodiments, the additional layer 22 is a photocatalytic layer that can catalyze hydrocarbon residues formed on the photomask into CO₂ and/or H₂O with EUV radiation. Thus, an in-situ self-cleaning of the mask surface is performed. In some embodiments, in the EUV scanner system, oxygen and hydrogen gases are injected into the EUV chamber to maintain the chamber pressure (e.g., at about 2 Pa). The chamber background gas can be a source of oxygen. In addition to the photocatalytic function, the photocatalytic layer is designed to have sufficient durability and resistance to various chemicals and various chemical processes, such as cleaning and etching. For example, ozonated water used to make the EUV reflective mask in the subsequent processes may damage the capping layer 20 made of Ru resulting in a significant EUV reflectivity drop. Further, after Ru oxidation, the Ru oxide is easily etched away by an etchant, such as C1₂ or CF₄ gas. In some embodiments, the photocatalytic layer includes one or more of titanium oxide (e.g.—TiO₂), tin oxide (e.g.—SnO), zinc oxide (e.g.—ZnO) and cadmium sulfide (e.g.—CdS). The thickness of the photocatalytic layer 22 is in a range from about 2 nm to about 10 nm in some embodiments, and is in a range from about 3 nm to about 7 nm in other embodiments. When the thickness is too thin, the photocatalytic layer may not sufficiently function as an etch stop layer. When the thickness is too large, the photocatalytic layer may absorb the EUV radiation.

In some embodiments, as shown in FIG. 2E, a substrate protection layer 12 is formed between the substrate 10 and the sacrificial layer 60. In some embodiments, the substrate protection layer 12 is made of Ru or a Ru compound, such as one or more of RuO, RuNb, RuNbO, RuZr and RuZrO. In some embodiments, the substrate protection layer 12 is made of the same material as or different material from the capping layer 20. The thickness of the substrate protection layer 12 is in a range from about 2 nm to about 10 nm in some embodiments.

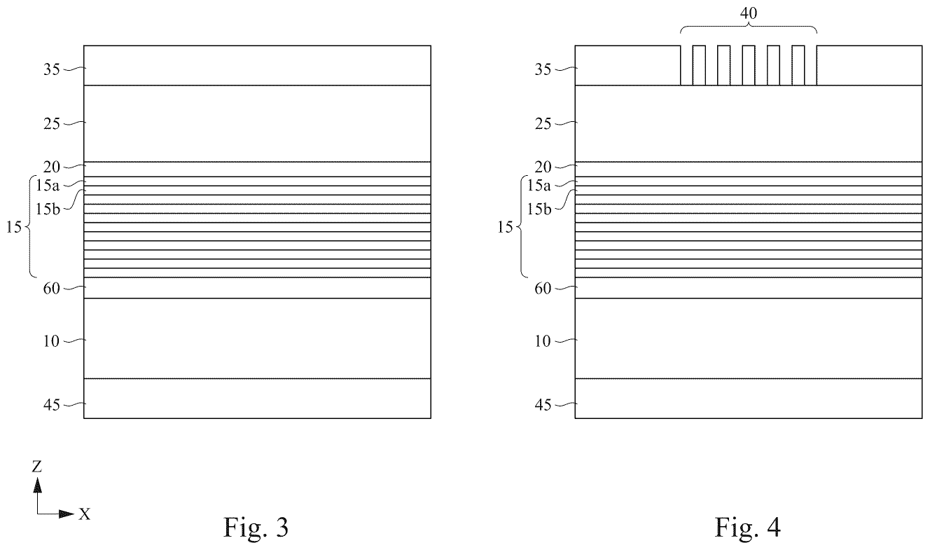

FIGS. 3-11 schematically illustrate a method of fabricating an EUV photomask for use in extreme ultraviolet lithography (EUVL) according to embodiments of the disclosure. It is understood that additional operations can be provided before, during, and after processes shown by FIGS. 3-11, and some of the operations described below can be replaced or eliminated for additional embodiments of the method. The order of the operations/processes may be interchangeable.

In the fabrication of an EUV photomask, a first photoresist layer 35 is formed over the absorber layer 25 of the EUV photomask blank as shown in FIG. 3. The photoresist layer 35 is selectively exposed to actinic radiation and the selectively exposed photoresist is developed to form a pattern 40, as shown in FIG. 4. In some embodiments, the actinic radiation is extreme ultraviolet (EUV) radiation, an electron beam, or an ion beam. In some embodiments, the pattern 40 corresponds to a pattern of semiconductor device features for which the EUV photomask will be used to form in subsequent operations.

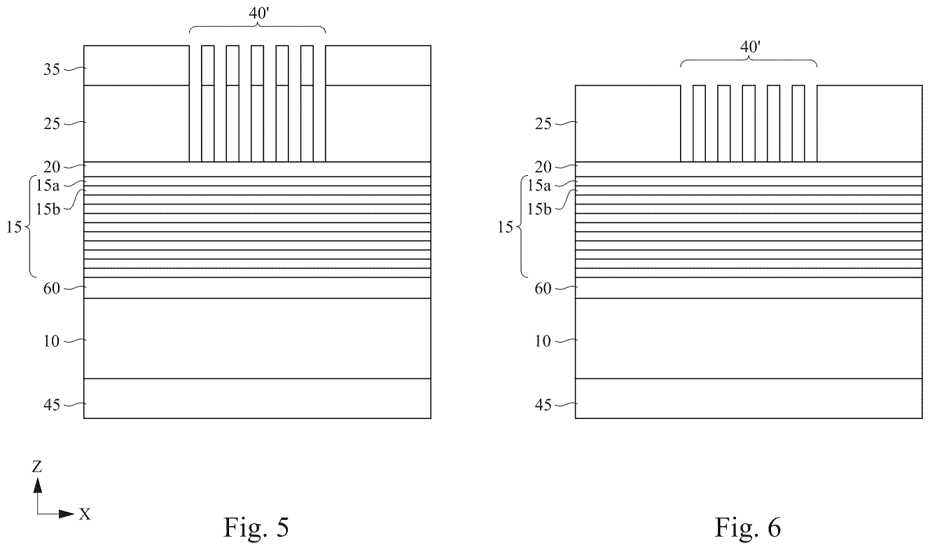

Next, the pattern 40 in the first photoresist layer 35 is extended into the absorber layer 25 forming a pattern 40′ in the absorber layer 25 exposing portions of the capping layer 20, as shown in FIG. 5. The pattern 40′ extended into the absorber layer 25 is formed by etching, in some embodiments, using a suitable wet or dry etchant that is selective to the absorber layer 25. In some embodiments, plasma dry etching is used. After the pattern 40′ in the absorber layer 25 is formed, the first photoresist layer 35 is removed by a photoresist stripper to expose the upper surface of the absorber layer 25, as shown in FIG. 6.

A second photoresist layer 50 is formed over the absorber layer 25 filling the pattern 40′ in the absorber layer 25. The second photoresist layer 50 is selectively exposed to actinic radiation such as electron beam, ion beam, EUV radiation, or deep ultraviolet (DUV) radiation. The selectively exposed second photoresist layer 50 is developed to form a pattern 55 in the second photoresist layer 50 as shown in FIG. 8. The pattern 55 corresponds to a black border surrounding the circuit patterns.

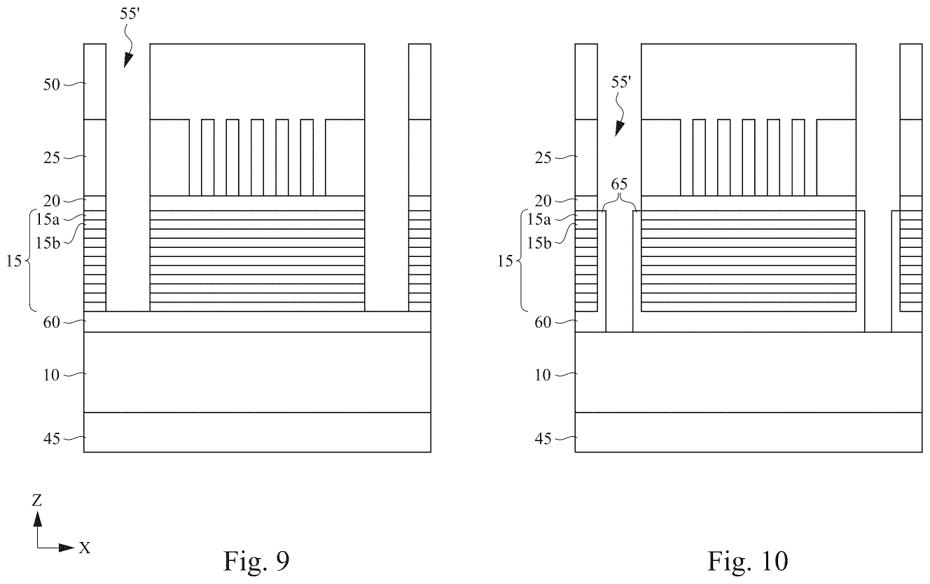

Next, the pattern 55 in the second photoresist layer 50 is extended into the absorber layer 25, capping layer 20, and Mo/Si multilayer 15 forming a black border 55′ exposing portions of the sacrificial layer 60, as shown in FIG. 9. In some embodiments, the black border 55′ is an opening or trench surrounding the pattern 40′ in the absorber layer 25. The black border 55′ is formed by etching, in some embodiments, using one or more suitable wet or dry etchants that are selective to each of the layers that are etched. In some embodiments, plasma dry etching is used.

Protective layers 65 are formed on the sidewalls of the black border 55′ by a dry, anisotropic etching of the exposed portions of the sacrificial layer 60 in the black border 55′. The portions of the sacrificial layer 60 that are removed by the etching operation are subsequently deposited on the sidewalls of the black border 55′ covering the sidewalls of the reflective multilayer 15, as shown in FIG. 10. In some embodiments, the sacrificial layer 60 is a metal layer including one or of Ru, Al, Rh, W, Ta, Hf, Ir, Ti, Pd, Zn, Cr, Ni, Zr, Pb, and alloys thereof. In some embodiments, the sacrificial layer 60 is doped with one or more of N, B, C, and O.

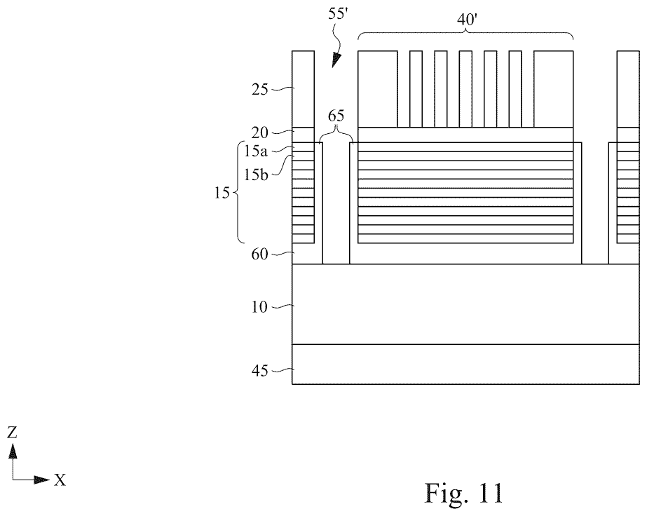

The second photoresist layer 50 is subsequently removed by a suitable photoresist stripper or plasma ashing to expose the upper surface of the absorber layer 25, as shown in FIG. 11.

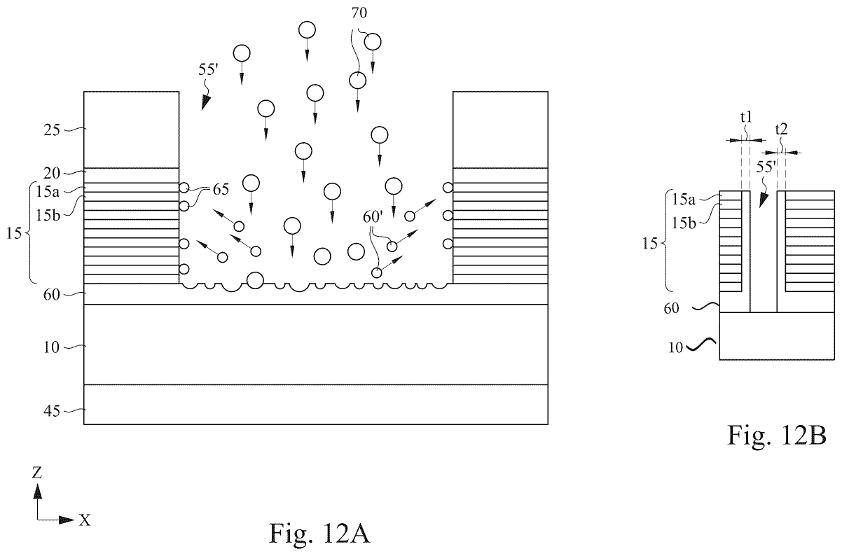

In some embodiments, the dry etching technique to form the protective layers 65 includes reactive ion etching (RIE), sputter etching, or a combination of RIE and sputtering techniques. In some embodiments, and as shown in FIG. 12A, a plasma is formed in a gas mixture using an RF power source, breaking the gas molecules into ions 70. In some embodiments, the gas mixture includes one or more of CH₃F, CH₄, HBr, O₂, and Ar. The ions 70 are accelerated towards, and react at, the surface of the material being etched, forming another gaseous material. This is the chemical part of reactive ion etching. There is also a physical etching aspect, which is a sputtering technique. If the ions have high enough energy, they can knock atoms out of the material to be etched without a chemical reaction. Thus, in some embodiments, the protective layer formation operation includes a combination of chemical and physical etching. As shown in FIG. 12A, portions of the sacrificial layer 60′ that are removed from the sacrificial layer 60 are subsequently deposited on the sidewalls of the black border 55′ forming the protective layer 65. Thus, during an etching operation of the sacrificial layer 60 in the black border 55′, the material of the sacrificial layer is transferred to the sidewalls of the black border 55′. This results in a protective layer 65 covering the sidewalls of the multilayer stack 15. In some embodiments, the entire exposed sidewalls of the multilayer stack 15 are covered by the protective layer 65. In some embodiments, the protective layer 65 extends along the Z direction to cover a portion or all of the capping layer 20 sidewall. In some embodiments, the protective layer 65 extends along the Z direction to cover a portion of the absorber layer 25 sidewall. In some embodiments, all of the sacrificial layer 60 is removed from the exposed surface of substrate 10 in the black border 55′ by the etching operation. In some embodiments, the endpoint of the sacrificial layer etching/protective layer deposition operation is determined using optical emission spectrometry (OES). The sacrificial layer 60 remains in the region where it is disposed between the multilayer stack 15 and the substrate 10.

In some embodiments, the dry etching is performed at a high source power and high bias power to provide the ions with sufficient momentum to sputter etch the sacrificial layer 60 surface and provide the material for the protective layer 65. In some embodiments, a source power ranging from about 250 W to about 2000 W is applied and a bias power ranging from about 20 W to about 200 W is applied to generate the etching plasma from the gas mixture. In other embodiments, the source power ranges from about 500 W to about 1000 W and the bias power ranges from about 40 W to about 100 W. The etching/deposition operation is performed in a chamber heated to a temperature of about 25° C. to about 150° C. in some embodiments, and heated to a temperature of about 50° C. to about 120° C. in other embodiments. At powers and temperatures outside the disclosed ranges there may be insufficient removal of the sacrificial layer 60 during the etching phase and insufficient formation of the protective layer 65 during the deposition phase. In some embodiments, the protective layer 65 has a thickness ranging from about 1 nm to about 12 nm, and in other embodiments, the thickness ranges from about 2 nm to about 6 nm. In some embodiments, the thickness t1 of the protective layer 65 on one sidewall is the same or different than the thickness t2 of the protective layer on a sidewall on an opposing side of the black border 55′, as shown in the detailed view of the black border 55′ region of FIG. 12B.

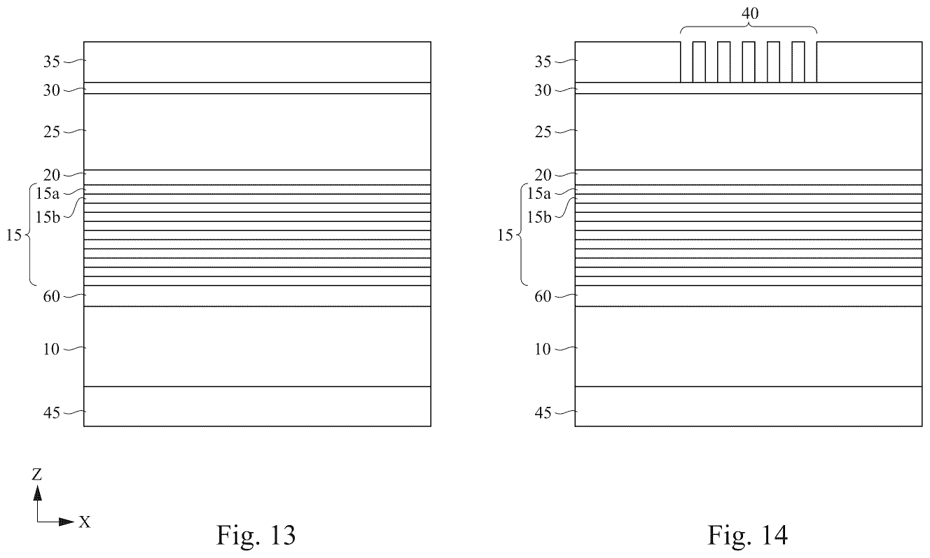

FIGS. 13-23 schematically illustrate a method of fabricating an EUV photomask for use in extreme ultraviolet lithography (EUVL) according to embodiments of the disclosure. It is understood that additional operations can be provided before, during, and after processes shown by FIGS. 13-23, and some of the operations described below can be replaced or eliminated for additional embodiments of the method. The order of the operations/processes may be interchangeable.

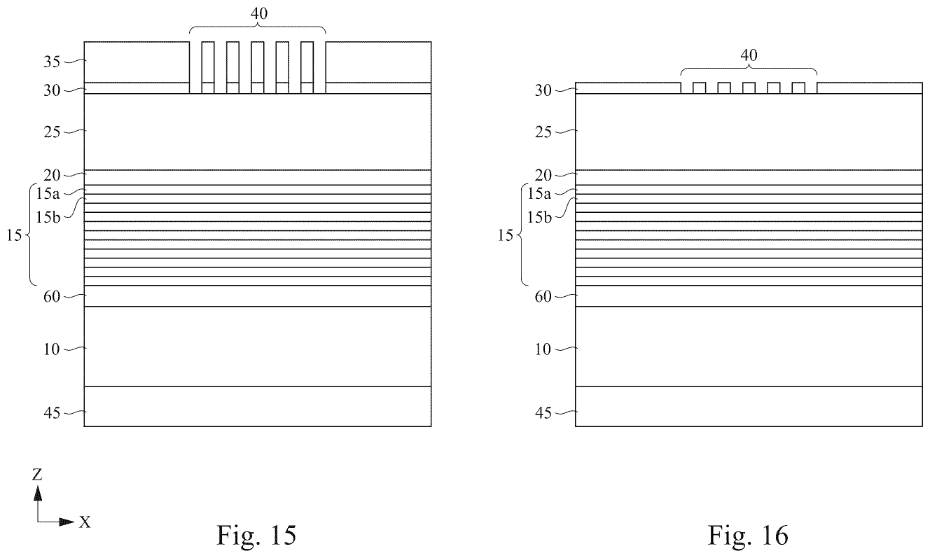

FIG. 13 shows a cross sectional view of an EUV photomask blank including a first photoresist layer 35 according to embodiments of the present disclosure. The structure of FIG. 13 is similar to the structure of FIG. 3 but with the addition of a hard mask layer 30 disposed over the absorber layer 25. The hard mask layer 30 may be formed of any of the materials disclosed herein for hard mask layers and may have a thickness as disclosed herein. The first photoresist layer 35 is subsequently patterned in FIG. 14, as disclosed herein in reference to FIG. 4. Then, the pattern 40 in the photoresist is extended into the hard mask layer 30 exposing portions of the absorber layer 25 using a suitable etching technique, such as anisotropic plasma etching, as shown in FIG. 15.

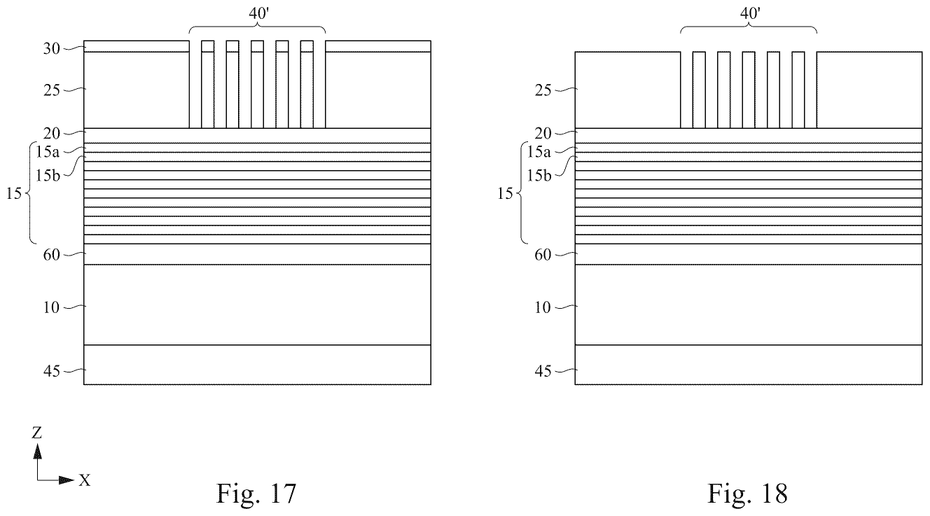

The first photoresist layer 35 is subsequently removed using a suitable photoresist stripper or plasma ashing operation, as shown in FIG. 16. Then, the pattern 40 in the hard mask layer 40 is extended into the absorber layer 25 forming a pattern 40′ in the absorber layer exposing a portion of the capping layer 20, as shown in FIG. 17. The pattern 40′ in the absorber layer is formed using a suitable wet or dry etchant that is selective to the absorber layer 25.

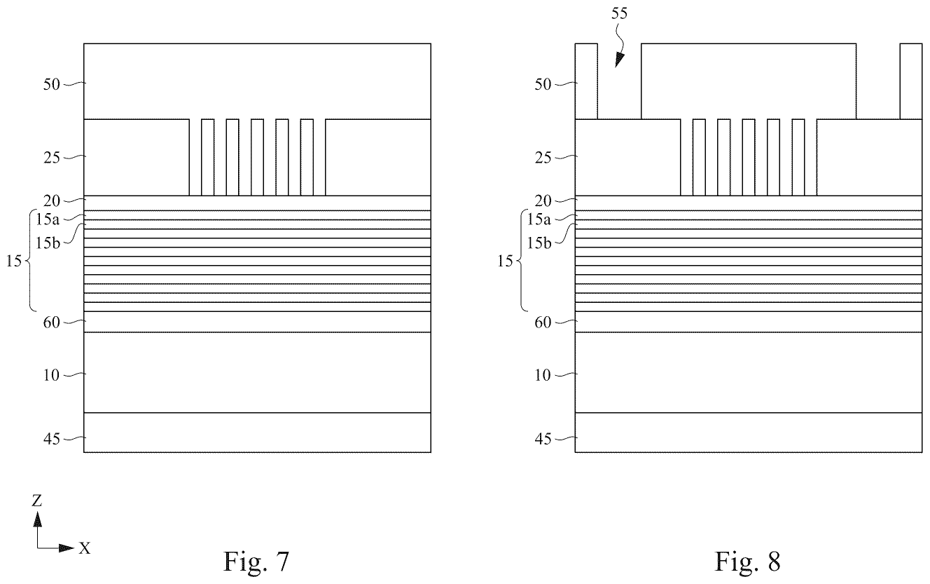

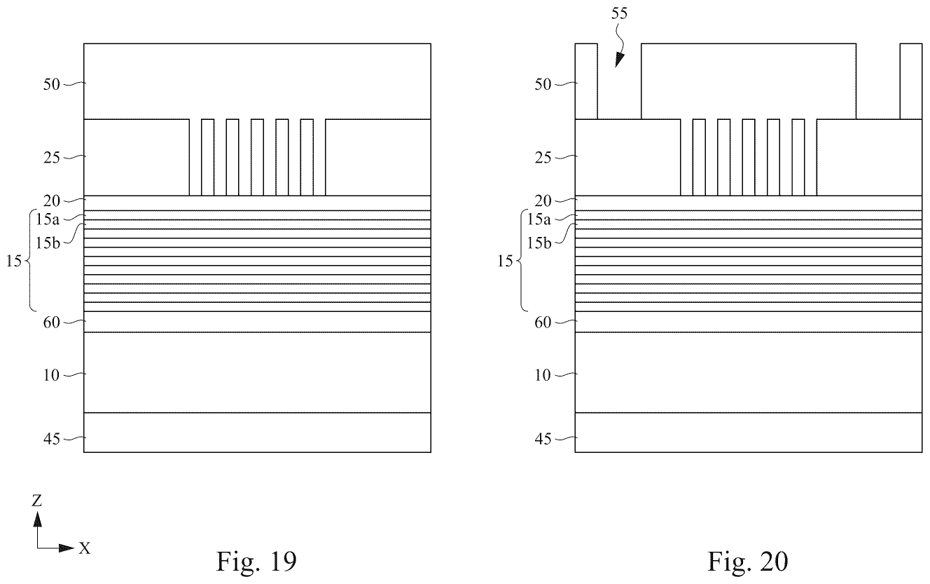

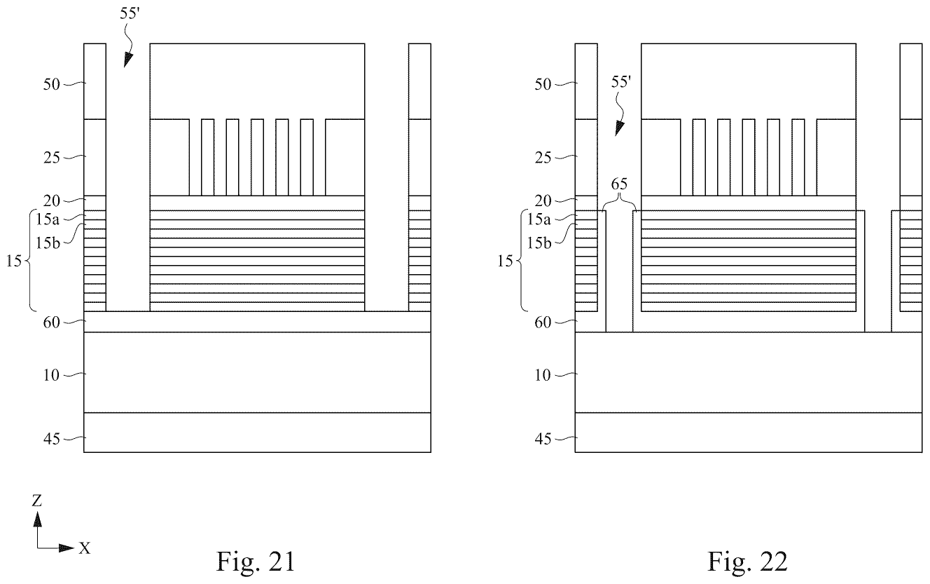

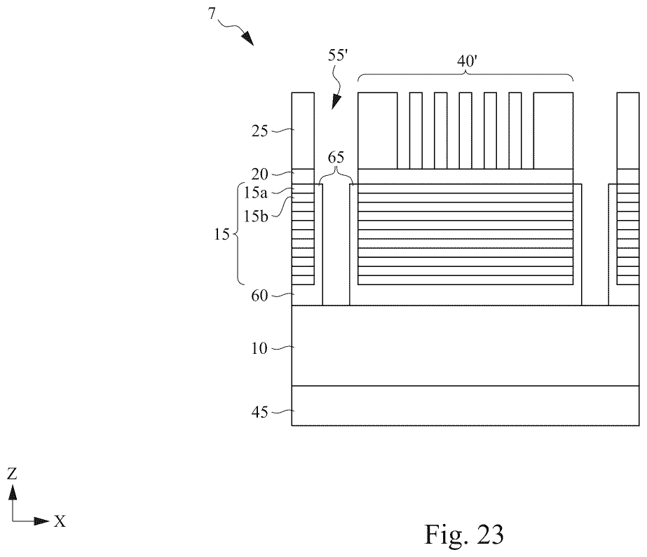

The hard mask layer is subsequently removed, as shown in FIG. 18, by a suitable wet or dry etching technique using a suitable etchant selective to the hard mask layer 30. As shown in FIG. 19, a second photoresist layer 50 is formed over the patterned absorber layer 25, as disclosed herein in reference to FIG. 7. The second photoresist layer 50 is subsequently patterned to form a pattern 55 corresponding to the black border region, as shown in FIG. 20, using techniques disclosed herein in reference to FIG. 8. Then, as explained in reference to FIG. 9, the black border 55′ is formed, as shown in FIG. 21 and explained in reference to FIG. 9. An etching/deposition operation is performed, as explained herein in reference to FIG. 10, to form the protective layers 65 over the sidewalls of the multilayer stack 15, as shown in FIG. 22. The second photoresist layer is removed, as shown in FIG. 23 and explained in reference to FIG. 11, to provide an EUV photomask according to embodiments of the disclosure.

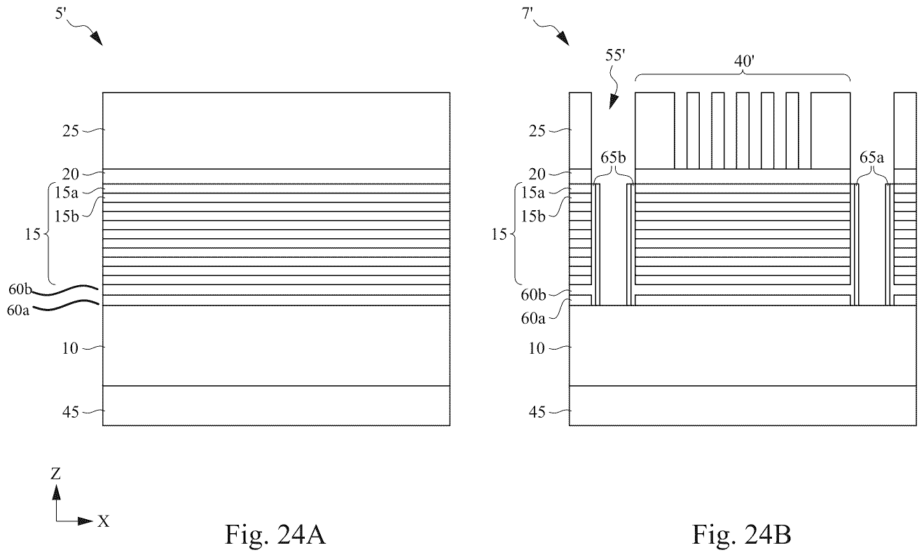

In another embodiment, the sacrificial layer includes a first sacrificial layer 60a disposed over the substrate 10 and a second sacrificial layer 60b disposed over the first sacrificial layer 60A, as shown in the EUV photomask blank 5′ in FIG. 24A. The first sacrificial layer 60a and the second sacrificial layer 60b can be made of different materials. In some embodiments, the first sacrificial layer 60a and the second sacrificial layer 60b are made of different metals. In other embodiments, the first sacrificial layer 60a and the second sacrificial layer 60b are made of the same metal, but one of the layers is doped with another element and the other layer is undoped, or each layer is doped with different elements.

The EUV photomask 7′ illustrated in FIG. 24B is formed in the same manner disclosed herein for the EUV photomasks 7 illustrated in FIGS. 11 and 23, except the etching/deposition operation of etching the sacrificial layer 60 and forming the protective layer 65 is formed in two stages. In the first stage, the second sacrificial layer 60b is etched using reactive ion etching, sputter etching, or a combination thereof to form a first protective layer 65b covering the sidewalls of the multilayer stack 15. Then, in the second stage, the first sacrificial layer 60a is etched using reactive ion etching, sputter etching, or a combination thereof to form a second protective layer 65a covering the first protective layer 65b. The etching/deposition operation is described herein with reference to FIG. 12A. The first sacrificial layer 60a and the second protective layer 65a are formed of the same material, and the second sacrificial layer 60b and the first protective layer 65b are formed of the same material. In some embodiments, the first and second sacrificial layers 60a, 60b are metal layers including one or more of Ru, Al, Rh, W, Ta, Hf, Ir, Ti, Pd, Zn, Cr, Ni, Zr, Pb, and alloys thereof. In some embodiments, the first and second sacrificial layers 60a, 60b are doped with one or more of N, B, C, and O. In some embodiments, the combined thicknesses of the first and second sacrificial layers 60a, 60b ranges from about 1 nm to about 60 nm, and in other embodiments, the combined thicknesses range from about 2 nm to about 30 nm. In some embodiments, the combined thickness of the first and second protective layers ranges from about 1 nm to about 12 nm, and in other embodiments, the combined thickness ranges from about 2 nm to about 6 nm.

In some embodiments, there are more than two sacrificial layers and corresponding number of protective layers. The methods and processes for forming a photomask having three or more sacrificial layers and protective layers are the same as forming a photomask having two sacrificial layers and protective layers, but there are three or more etching/deposition stages corresponding to the number of sacrificial and protective layers.

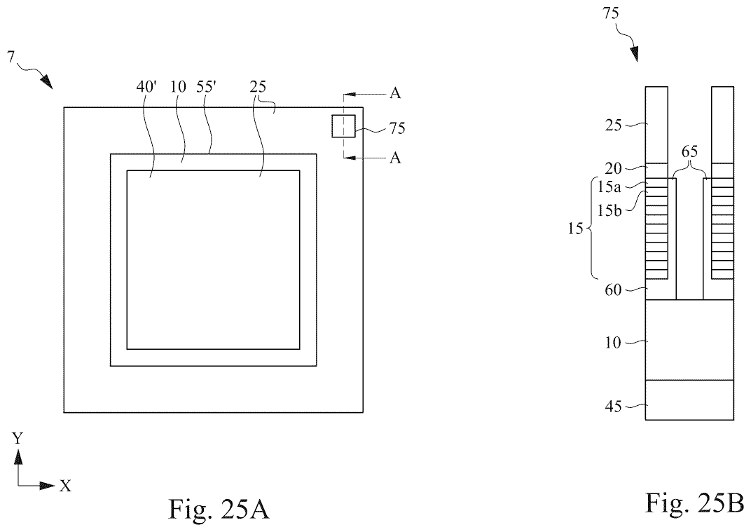

In some embodiments, a two dimensional bar code 75 to identify the photomask is formed in a peripheral area of the photomask, as shown in FIG. 25A. The bar code is a unique identifier for each photomask, which is read by the EUV scanner during the photolithographic exposure operation. FIG. 25A is a schematic plan view of an EUV photomask according to embodiments of the disclosure. In some embodiments, the bar code 75 is formed in a corner of the photomask outside the black border 55′. FIG. 25B illustrates a cross-sectional view of the bar code taken along line A-A of FIG. 25A. The bar code feature is formed in a similar manner disclosed herein for forming the black border 55 and the protective layer 65.

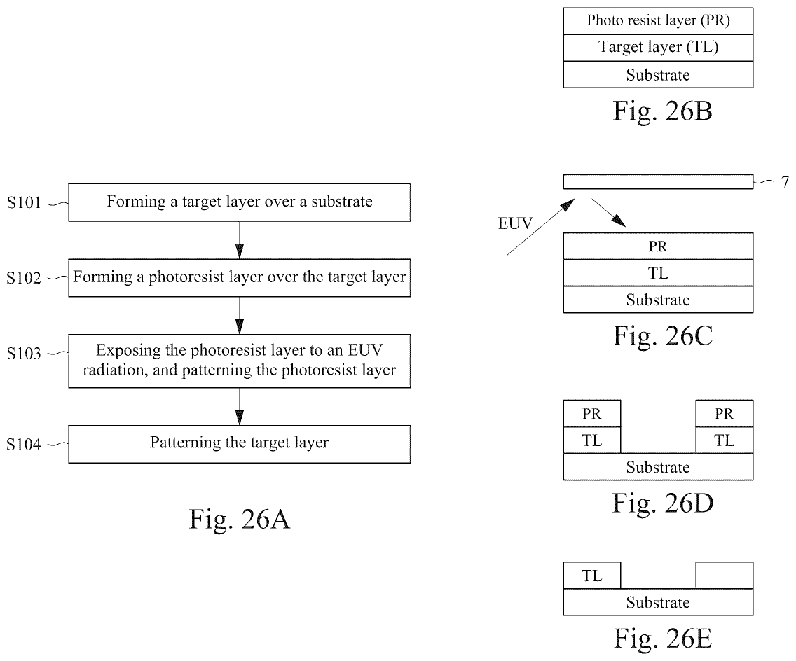

FIG. 26A shows a flowchart of a method of making a semiconductor device, and FIGS. 26B, 26C, 26D, and 26E show a sequential manufacturing operation of the method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. In operation S101 of FIG. 26A, a target layer to be patterned is formed over the semiconductor substrate. In certain embodiments, the target layer is the semiconductor substrate. In some embodiments, the target layer includes a conductive layer, such as a metallic layer or a polysilicon layer, a dielectric layer, such as silicon oxide, silicon nitride, SiON, SiOC, SiOCN, SiCN, hafnium oxide, or aluminum oxide, or a semiconductor layer, such as an epitaxially formed semiconductor layer. In some embodiments, the target layer is formed over an underlying structure, such as isolation structures, transistors, or wirings. In operation S102, a photoresist layer PR is formed over the target layer TL, as shown in FIG. 26B. The photoresist layer PR is sensitive to the radiation from the exposure source during a subsequent photolithography exposing process. In the present embodiment, the photoresist layer PR is sensitive to EUV radiation used in the photolithography exposing process. The photoresist layer PR may be formed over the target layer TL by spin-on coating or other suitable technique. The coated photoresist layer PR may be further baked to drive out solvent in the photoresist layer.

In operation S103, the photoresist layer is patterned using an EUV reflective photomask 7 described in the embodiments disclosed herein, as shown in FIG. 26C. The patterning of the photoresist layer includes performing a photolithographic exposure operation by an EUV exposing system using an EUV photomask according to any of the embodiments disclosed herein. During the exposing process, the integrated circuit (IC) design pattern defined on the EUV mask is imaged to the photoresist layer to form a latent pattern thereon. The patterning of the photoresist layer further includes developing the exposed photoresist layer to form a patterned photoresist layer having one or more openings. In one embodiment where the photoresist layer is a positive tone photoresist layer, the exposed portions of the photoresist layer are removed during the developing process. In other embodiments, where the photoresist layer is a negative tone photoresist layer, the unexposed portions of the photoresist layer are removed during the developing process. The patterning of the photoresist layer may further include other process steps, such as various baking steps at different stages. For example, a post-exposure-baking (PEB) process may be implemented after the photolithography exposing process and before the developing process.

The target layer TL is subsequently patterned using the patterned photoresist layer PR as an etching mask, as shown in FIG. 26D. In some embodiments, the patterning the target layer includes applying an etching process to the target layer TL using the patterned photoresist layer PR as an etch mask. The portions of the target layer TL exposed within the openings of the patterned photoresist layer are etched while the remaining portions are protected from etching. Further, the patterned photoresist layer may be removed by a wet stripping operation or a plasma ashing operation, as shown in FIG. 26E.

Additional operations may be performed on the structure of FIG. 26E, including forming transistors, including fin field effect transistors (FinFETs), gate-all-around field effect transistors (GAA FETs), bipolar transistors, and planar transistors; memory devices; capacitors; insulating layers; and metal wiring layers, including interconnects and vias. The structure of FIG. 26E. The structure of FIG. 21 may be part of a larger integrated circuit, including additional devices and components.

Embodiments of the present disclosure protect the sidewalls of the reflective multilayer stack of an EUV photomask from damage during semiconductor manufacturing processes. The protective layer 65 on the sidewalls of the reflective multilayer stack 15 extends the service life of the EUV photomask and maintains the high reflectivity of the photomask throughout the photomask's service life in some embodiments. The protective layer 65 on the sidewalls of the reflective multilayer stack 65 prevents stray light reflections from degrading the EUV image in some embodiments, thus improving pattern resolution in the photoresist.

It will be understood that not all advantages have been necessarily discussed herein, no particular advantage is required for all embodiments or examples, and other embodiments or examples may offer different advantages.

An embodiment of the disclosure is a method of manufacturing a reflective mask, including forming a sacrificial layer over a substrate and forming a reflective multilayer over the sacrificial layer. A capping layer is formed over the reflective multilayer. An absorber layer is formed over the capping layer. An opening is formed in the absorber layer, the capping layer, and the reflective layer exposing a portion of the sacrificial layer, and a protective layer is formed along sidewalls of the opening. The protective layer is made of material from the sacrificial layer. In an embodiment, the protective layer is formed by etching the sacrificial layer. In an embodiment, the etching is a reactive ion etch. In an embodiment, the etching exposes a portion of the substrate. In an embodiment, an entire sidewall of the reflective multilayer is covered by the protective layer. In an embodiment, the sacrificial layer includes one or more of Ru, Al, Rh, W, Ta, Hf, Ir, Ti, Pd, Zn, Cr, Ni, Zr, Pb, and alloys thereof. In an embodiment, the sacrificial layer is doped with one or more of N, B, C, and O.

Another embodiment of the disclosure is a method of manufacturing an extreme ultraviolet mask including forming a sacrificial layer over a substrate. A multilayer stack including alternately stacked silicon and molybdenum layers is formed over the sacrificial layer. A capping layer is formed over the multilayer stack and an absorber layer is formed over the capping layer. The absorber layer, the capping layer, and the multilayer stack are patterned to form an opening exposing a portion of the sacrificial layer. The sacrificial layer is etched to form a protective layer along sidewalls of the opening. In an embodiment, the etching uses one or more gases selected from CH₃F, CH₄, HBr, O₂, and Ar. In an embodiment, the etching exposes a portion of the substrate. In an embodiment, an entire sidewall of the multilayer stack is covered by the protective layer. In an embodiment, the sacrificial layer includes one or more of Ru, Al, Rh, W, Ta, Hf, Ir, Ti, Pd, Zn, Cr, Ni, Zr, Pb, and alloys thereof. In an embodiment, the sacrificial layer is doped with one or more of N, B, C, and O. In an embodiment, the protective layer has a thickness ranging from 1 nm to 12 nm.

Another embodiment of the disclosure is a method of manufacturing a reflective mask including forming a metal layer over a substrate and forming a reflective multilayer stack over the metal layer. A capping layer is formed over the multilayer stack. An absorber layer is formed over the capping layer. A photoresist layer is formed over the absorber layer. The photoresist layer is selectively exposed to actinic radiation and the selectively exposed photoresist layer is developed. The absorber layer, the capping layer, and the reflective multilayer stack are etched to form an opening exposing a portion of the metal layer. Metal is transferred from the exposed portion of the metal layer to a sidewall of the reflective multilayer stack in the opening. In an embodiment, an entire sidewall of the reflective multilayer stack is covered by the metal. In an embodiment, the metal includes one or more of Ru, Al, Rh, W, Ta, Hf, Ir, Ti, Pd, Zn, Cr, Ni, Zr, Pb, and alloys thereof. In an embodiment, the metal layer is doped with one or more of N, B, C, and O. In an embodiment, the metal is transferred from the metal layer to the sidewall of the reflective multilayer by a physical etching operation. In an embodiment, the actinic radiation is an electron beam.

Another embodiment of the disclosure is a reflective mask including a substrate and a first metal layer disposed over the substrate. A reflective multilayer is disposed over the first metal layer. A capping layer is disposed over the reflective multilayer and an absorber layer is disposed over the capping layer. A pattern is formed in the absorber layer. An opening in the absorber layer, the capping layer, and the reflective multilayer exposes a portion of the substrate surrounding the pattern. A second metal layer is disposed over sidewalls of the reflective multilayer in the opening, wherein the first metal layer and the second metal layer are formed of a same material. In an embodiment, the first metal layer extends in a first direction along a main surface of the substrate. In an embodiment, the second metal layer extends in a second direction perpendicular to the first direction. In an embodiment, the first metal layer and the second metal layer include one or more of Ru, Al, Rh, W, Ta, Hf, Ir, Ti, Pd, Zn, Cr, Ni, Zr, Pb, and alloys thereof. In an embodiment, the first metal layer is doped with one or more of N, B, C, and O. In an embodiment, the second metal layer has a thickness ranging from 1 nm to 12 nm. In an embodiment, the reflective multilayer includes a stack of alternating silicon layers and molybdenum layers. In an embodiment, an entire sidewall of the reflective multilayer is covered by the second metal layer. In an embodiment, the absorber layer includes one or more of a Cr-based material, a Ta-based material, an Ir-based material, a Pt-based material, or a Co-based material. In an embodiment, the capping layer includes ruthenium or a ruthenium alloy.

Another embodiment of the disclosure is an extreme ultraviolet mask including a substrate and a first metal layer disposed over the substrate. A multilayer stack of alternating silicon and molybdenum layers is disposed over the first metal layer. A capping layer is disposed over the multilayer stack and an absorber layer is disposed over the capping layer. A black border surrounds the first metal layer, the multilayer stack, the absorber layer, and the capping layer. A protective layer is disposed over sidewalls of the black border. The protective layer and the first metal layer are formed of a same material. In an embodiment, the protective layer has a thickness ranging from 1 nm to 12 nm. In an embodiment, an entire sidewall of the multilayer stack is covered by the protective layer. In an embodiment, the first metal layer and the protective layer include one or more of Ru, Al, Rh, W, Ta, Hf, Ir, Ti, Pd, Zn, Cr, Ni, Zr, Pb, and alloys thereof. In an embodiment, the first metal layer is doped with one or more of N, B, C, and O.

Another embodiment is a reflective mask a silica-based substrate and a first metal layer made of a first metal disposed over the substrate. A second metal layer made of a second metal different than the first metal is disposed over the first metal layer. A multilayer stack of alternating silicon layers and molybdenum layers is disposed over the second metal layer. A capping layer is disposed over the multilayer stack. An absorber layer having a pattern formed therein is disposed over the capping layer. A trench in the absorber layer, the capping layer, and the multilayer stack exposes a portion of the substrate surrounding the pattern. A first protective layer is disposed over sidewalls of the multilayer stack in the trench. The first protective layer has a first main surface facing the sidewalls of the multilayer stack. A second protective layer is disposed over a second main surface of the first protective layer opposing the first main surface of the first protective layer. The first metal layer and the second protective layer are formed of a same material, and the second metal layer and the first protective layer are formed of a same material. In an embodiment, the first metal layer and the second metal layer include one or more of Ru, Al, Rh, W, Ta, Hf, Ir, Ti, Pd, Zn, Cr, Ni, Zr, Pb, and alloys thereof. In an embodiment, the first metal layer is doped with one or more of N, B, C, and O. In an embodiment, entire sidewalls of the multilayer stack are covered by the first protective layer. In an embodiment, the absorber layer includes one or more of Cr, Ta, Ir, Pt, or Co.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a reflective mask, comprising:
forming a sacrificial layer over a substrate;
forming a reflective multilayer over the sacrificial layer;
forming a capping layer over the reflective multilayer;
forming an absorber layer over the capping layer;
forming an opening in the absorber layer, the capping layer, and the reflective layer exposing a portion of the sacrificial layer; and
forming a protective layer along sidewalls of the opening,
wherein the protective layer is made of material from the sacrificial layer.

2. The method according to claim 1, wherein the protective layer is formed by etching the sacrificial layer.

3. The method according to claim 2, wherein the etching is a reactive ion etch.

4. The method according to claim 2, the etching exposes a portion of the substrate.

5. The method according to claim 1, wherein an entire sidewall of the reflective multilayer is covered by the protective layer.

6. The method according to claim 1, wherein the sacrificial layer comprises one or more of Ru, Al, Rh, W, Ta, Hf, Ir, Ti, Pd, Zn, Cr, Ni, Zr, Pb, and alloys thereof.

7. The method according to claim 6, wherein the sacrificial layer is doped with one or more of N, B, C, and O.

8. A method of manufacturing an extreme ultraviolet mask, comprising:
forming a sacrificial layer over a substrate;
forming a multilayer stack comprising alternately stacked silicon and molybdenum layers over the sacrificial layer;
forming a capping layer over the multilayer stack;
forming an absorber layer over the capping layer;
patterning the absorber layer, capping layer, and the multilayer stack to form an opening exposing a portion of the sacrificial layer; and
etching the sacrificial layer to form a protective layer along sidewalls of the opening.

9. The method according to claim 8, wherein the etching uses one or more gases selected from CH₃F, CH₄, HBr, O₂, and Ar.

10. The method according to claim 8, the etching exposes a portion of the substrate.

11. The method according to claim 8, wherein an entire sidewall of the multilayer stack is covered by the protective layer.

12. The method according to claim 8, wherein the sacrificial layer comprises one or more of Ru, Al, Rh, W, Ta, Hf, Ir, Ti, Pd, Zn, Cr, Ni, Zr, Pb, and alloys thereof.

13. The method according to claim 12, wherein the sacrificial layer is doped with one or more of N, B, C, and O.

14. The method according to claim 8, wherein the protective layer has a thickness ranging from 1 nm to 12 nm.

15. A reflective mask, comprising:
a substrate;
a first metal layer disposed over the substrate;
a reflective multilayer disposed over the first metal layer;
a capping layer disposed over the reflective multilayer;
an absorber layer disposed over the capping layer,
wherein a pattern is formed in the absorber layer;
an opening in the absorber layer, the capping layer, and the reflective multilayer exposing a portion of the substrate surrounding the pattern; and
a second metal layer disposed over sidewalls of the reflective multilayer in the opening,
wherein the first metal layer and the second metal layer are formed of a same material.

16. The reflective mask of claim 15, wherein the first metal layer extends in a first direction along a main surface of the substrate.

17. The reflective mask of claim 16, wherein the second metal layer extends in a second direction perpendicular to the first direction.

18. The reflective mask of claim 15, wherein the first metal layer and the second metal layer comprise one or more of Ru, Al, Rh, W, Ta, Hf, Ir, Ti, Pd, Zn, Cr, Ni, Zr, Pb, and alloys thereof.

19. The reflective mask of claim 18, wherein the first metal layer is doped with one or more of N, B, C, and O.

20. The reflective mask of claim 15, wherein the second metal layer has a thickness ranging from 1 nm to 12 nm.
